(19) United States
(12) Patent Application Publication
(10) Pub. No.: US 2024/0096721 A1
(43) Pub. Date: Mar. 21, 2024

(54) ELECTRONIC PACKAGE AND MANUFACTURING METHOD THEREOF

(71) Applicant: AaltoSemi Inc., Nanjing City (CN)

(72) Inventors: Chien-Kuang LAI, Nanjing City (CN); Andrew C. CHANG, Nanjing City (CN); Min-Yao CHEN, Nanjing City (CN)

(21) Appl. No.: 18/456,736

(22) Filed: Aug. 28, 2023

(30) Foreign Application Priority Data
Sep. 19, 2022 (TW) 111135389

(51) Int. Cl. H01L 23/31; H01L 21/56; H01L 23/00; H01L 23/498

(52) U.S. Cl. CPC H01L 23/3121; H01L 21/56; H01L 23/49822; H01L 24/16; H01L 2224/16227

(57) ABSTRACT

An electronic package of which the manufacturing method is to dispose an electronic element on a circuit portion, encapsulate the electronic element with an Ajinomoto build-up film (ABF) used as an encapsulating layer, form a wiring layer on the encapsulating layer, and form a conductive via in the encapsulating layer. Therefore, the wiring layer can be well bonded onto the encapsulating layer as the ABF material is used as the encapsulating layer.

### BACKGROUND

### 1. Technical Field

The present disclosure relates to a semiconductor packaging process, and more particularly, to an electronic package that can improve reliability and a manufacturing method thereof.

### 2. Description of Related Art

With the vigorous development of the electronic industry, electronic products are gradually developing towards the trend of multi-function and high performance. At the same time, technologies currently used in the field of chip packaging include, for example, wafer level packaging (WLP), chip scale package (CSP), direct chip attached (DCA), multi-chip module (MCM) package, and other packaging types of packaging modules.

FIG. 1A to FIG. 1E are schematic cross-sectional views showing a method of manufacturing a conventional semiconductor package 1.

As shown in FIG. 1A, a release layer 100 is formed on a carrier 10. Next, a plurality of semiconductor elements 17 are placed on the release layer 100, wherein the semiconductor elements 17 have active surfaces 17a and inactive surfaces 17b opposing the active surfaces 17a. A plurality of electrode pads 170 are formed on the active surface 17a, and each of the semiconductor elements 17 is adhered onto the release layer 100 via the active surface 17a thereof.

As shown in FIG. 1B, an encapsulating layer 18 made of such as epoxy resin is formed on the release layer 100 to cover the semiconductor elements 17.

As shown in FIG. 1C, the carrier 10 and the semiconductor elements 17 are separated by the release layer 100, so that the active surfaces 17a of the semiconductor elements 17 are exposed.

As shown in FIG. 1D, a wiring structure 15 is formed on the encapsulating layer 18 and the active surface 17a of the semiconductor element 17, and the wiring structure 15 includes at least one dielectric layer 150 and a wiring layer 151 bonded to the dielectric layer 150, so that the wiring layer 151 is electrically connected to the electrode pad 170 of the semiconductor element 17. Next, a solder-resist layer 16 is formed on the wiring structure 15, and a portion of the surface of the wiring layer 151 is exposed from the solder-resist layer 16 for bonding a conductive element 19 such as a solder ball.

As shown in FIG. 1E, a singulation process is performed along a cutting path L shown in FIG. 1D to obtain a plurality of the semiconductor packages 1.

However, in the conventional semiconductor package 1, since the encapsulating layer 18 is made of epoxy resin, the bonding force between the encapsulating layer 18 and the metal material such as copper is poor. As a result, the encapsulating layer 18 needs to be covered with the dielectric layer 150 made of such as prepreg (PP) before forming the wiring layer 151. Consequently, the manufacturing time and the manufacturing materials of the wiring structure 15 are greatly increased, making it difficult to reduce the manufacturing cost.

Furthermore, in the conventional semiconductor package 1, the encapsulating layer 18 is made of epoxy resin, so if the upper and lower sides of the encapsulating layer 18 need to be electrically connected, the conductive pillars need to be electroplated on the carrier 10 first, then the conductive pillars will be covered with the encapsulating layer 18, and then a grinding operation will be performed to expose the end surfaces of the conductive pillars. Therefore, the manufacturing process of the copper pillars and the grinding operation are required. As a result, the manufacturing time and the manufacturing materials are increased, making the manufacturing cost difficult to be reduced. Further, the manufacturing steps are rigmarole, so that the production efficiency is poor.

Also, in the conventional semiconductor package 1, since the encapsulating layer 18 is made of epoxy resin, only a single unit specification or a wafer size specification can be used for manufacturing. Therefore, the efficiency is difficult to be improved and the production cost can hardly be reduced, resulting in unfavorable mass production.

Therefore, there is a need for a solution that addresses the aforementioned shortcomings in the prior art.

### SUMMARY

In view of the aforementioned shortcomings of the prior art, the present disclosure provides an electronic package, which comprises: a circuit portion having at least one insulating layer and a circuit layer bonded to the insulating layer, wherein the insulating layer is defined with a first surface and a second surface opposing the first surface, and the circuit layer is exposed from the first surface of the insulating layer; an electronic element disposed on the first surface of the insulating layer of the circuit portion and electrically connected to the circuit layer; an encapsulating layer formed on the first surface of the insulating layer of the circuit portion and covering the electronic element, wherein the encapsulating layer is an Ajinomoto build-up film; and a wiring layer formed on the encapsulating layer, wherein the wiring layer is formed with at least one conductive via in the encapsulating layer, and the at least one conductive via is electrically connected to the circuit layer.

The present disclosure also provides a method of manufacturing an electronic package, the method comprises: providing a circuit portion having at least one insulating layer and a circuit layer bonded to the insulating layer, wherein the insulating layer is defined with a first surface and a second surface opposing the first surface, and the circuit layer is exposed from the first surface of the insulating layer; disposing an electronic element on the first surface of the insulating layer of the circuit portion, wherein the electronic element is electrically connected to the circuit layer; forming an encapsulating layer on the first surface of the insulating layer of the circuit portion to cover the electronic element, wherein the encapsulating layer is an Ajinomoto build-up film; and forming a wiring layer on the encapsulating layer, wherein the wiring layer extends into the encapsulating layer to form at least one conductive via electrically connected to the circuit layer.

In the aforementioned electronic package and method, the electronic element is a passive element.

In the aforementioned electronic package and method, the electronic element is electrically connected to the circuit layer via a plurality of conductive bumps.

In the aforementioned electronic package and method, a material forming the encapsulating layer is different from a material forming the insulating layer.

In the aforementioned electronic package and method, the present disclosure further comprises forming another wiring layer on the second surface of the insulating layer, and forming at least one conductive blind via in the insulating layer, wherein the at least one conductive blind via is electrically connected to the circuit layer and the another wiring layer.

As can be understood from the above, in the electronic package and the manufacturing method thereof according to the present disclosure, the ABF material is used as the encapsulating layer, so that the wiring layer can be well bonded onto the encapsulating layer. Therefore, compared with the prior art, the manufacturing method of the present disclosure can directly form the wiring layer on the encapsulating layer without forming a dielectric layer used to bond the wiring layer, so that the manufacturing time and the manufacturing materials can be effectively saved, and the manufacturing cost can be effectively reduced.

Furthermore, the manufacturing method of the present disclosure can directly process the ABF material by laser to form conductive vias. Therefore, compared with the prior art, the manufacturing method of the present disclosure does not need to perform the manufacturing process of copper pillars and grinding operations, which not only saves manufacturing time and manufacturing materials to reduce manufacturing costs, but also can greatly reduce manufacturing steps to facilitate improving production efficiency.

Also, since the manufacturing method of the present disclosure uses the ABF material as the encapsulating layer, a full-panel specification can be adopted. Therefore, compared with the prior art, the present disclosure can greatly improve the efficiency and reduce the production cost to facilitate mass production.

### BRIEF DESCRIPTION OF THE DRAWINGS

FIG. 1A to FIG. 1E are schematic cross-sectional views showing a method of manufacturing a conventional semiconductor package.

FIG. 2A to FIG. 2F are schematic cross-sectional views illustrating a method of manufacturing an electronic package according to a first embodiment of the present disclosure.

FIG. 3A to FIG. 3B are schematic cross-sectional views illustrating a method of manufacturing an electronic package according to a second embodiment of the present disclosure.

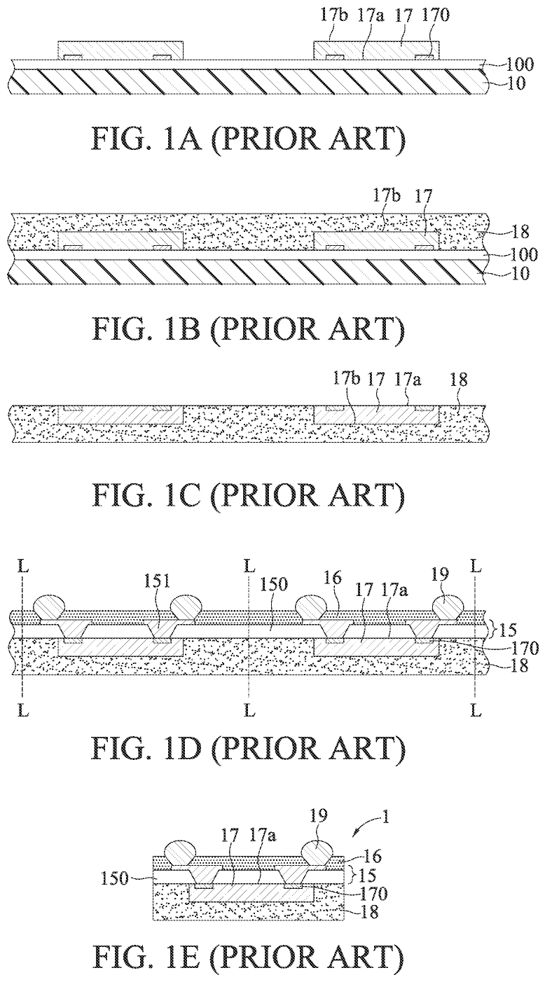

### DETAILED DESCRIPTION

Implementations of the present disclosure are described below by embodiments. Other advantages and technical effects of the present disclosure can be readily understood by one of ordinary skill in the art upon reading the disclosure of this specification.

It should be noted that the structures, ratios, sizes shown in the drawings appended to this specification are provided in conjunction with the disclosure of this specification in order to facilitate understanding by those skilled in the art. They are not meant, in any ways, to limit the implementations of the present disclosure, and therefore have no substantial technical meaning. Without influencing the effects created and objectives achieved by the present disclosure, any modifications, changes or adjustments to the structures, ratios, or sizes are construed as falling within the scope covered by the technical contents disclosed herein. Meanwhile, terms such as “on,” “above,” “first,” “second,” “a,” “one,” and the like, are for illustrative purposes, and are not meant to limit the scope implementable by the present disclosure. Any changes or adjustments made to the relative relationships, without substantially modifying the technical contents, are also to be construed as within the scope implementable by the present disclosure.

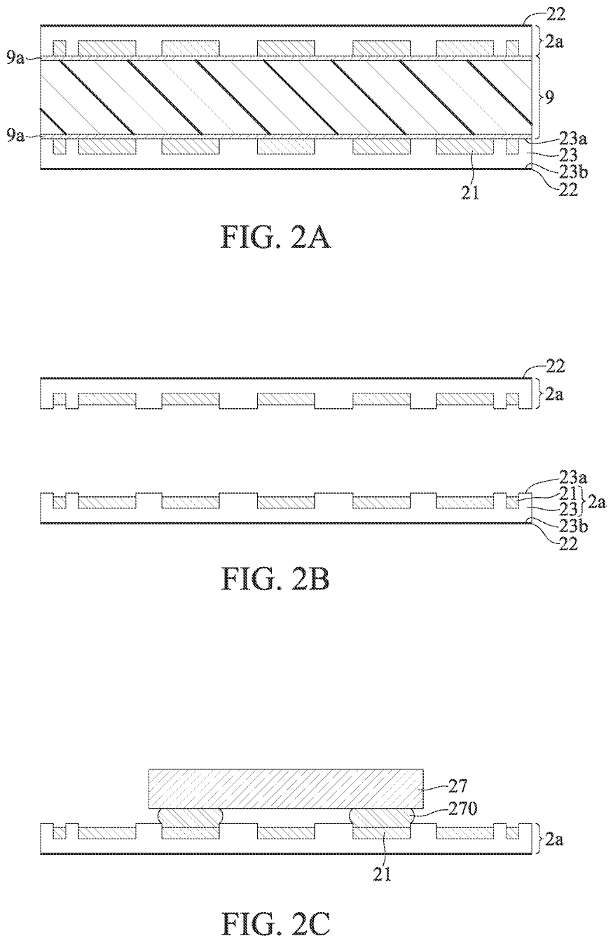

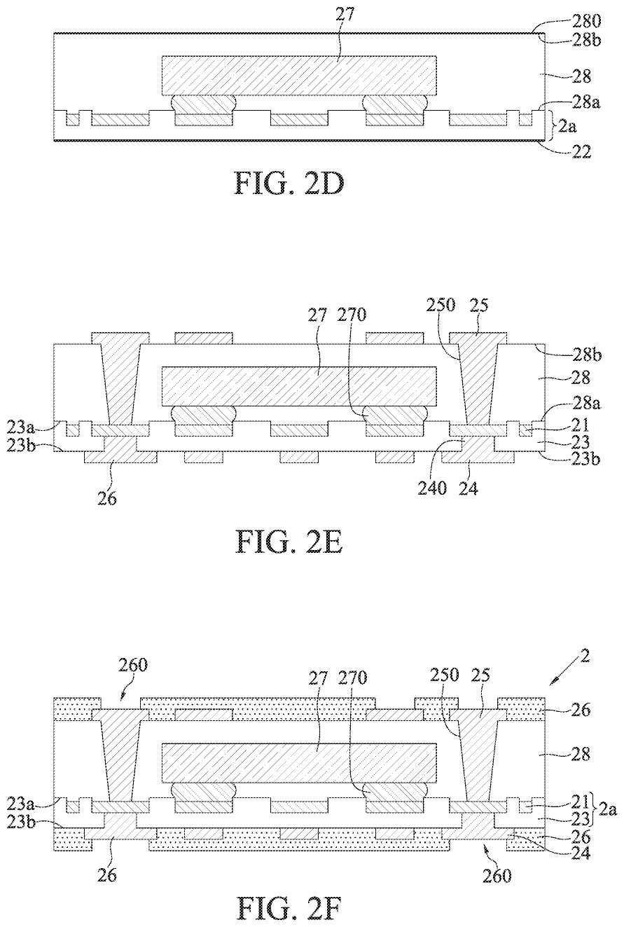

FIG. 2A to FIG. 2F are schematic cross-sectional views illustrating a method of manufacturing an electronic package 2 according to a first embodiment of the present disclosure.

As shown in FIG. 2A, a circuit layer 21 is formed on a carrier 9, and then an insulating layer 23 is formed on the carrier 9, so that the circuit layer 21 is covered by the insulating layer 23, wherein the circuit layer 21 and the insulating layer 23 are served as a circuit portion 2a.

In an embodiment, the opposite sides of the carrier 9 have metal surfaces 9a, so that the carrier 9 is such as a copper foil substrate, and the circuit portion 2a is manufactured on each of the metal surfaces 9a.

Furthermore, the insulating layer 23 is a dielectric layer and is made of such as polybenzoxazole (PBO), polyimide (PI), prepreg (PP), or other dielectric materials.

Also, the insulating layer 23 is defined with a first surface 23a and a second surface 23b opposing the first surface 23a, and the insulating layer 23 is bonded to the metal surface 9a of the carrier 9 via the first surface 23a thereof. For example, the insulating layer 23 is formed on the carrier 9 in a manner of pressing/laminating, so that a first metal layer 22 can be formed on the second surface 23b of the insulating layer 23 to facilitate pressing/laminating the insulating layer 23 on the carrier 9. Further, after the insulating layer 23 is bonded to the copper foil, the first metal layer 22 is exposed.

As shown in FIG. 2B, the circuit portion 2a and the first metal layer 22 thereon are separated from the carrier 9 by peeling, wherein the circuit layer 21 is exposed from the first surface 23a of the insulating layer 23.

In an embodiment, the copper foil is required to be removed by etching, so a portion of the material of the circuit layer 21 is slightly etched, such that the circuit layer 21 is recessed into the first surface 23a of the insulating layer 23. In other words, the surface of the circuit layer 21 is lower than the first surface 23a of the insulating layer 23.

As shown in FIG. 2C, at least one electronic element 27 is disposed on the first surface 23a of the insulating layer 23 of the circuit portion 2a, so that the electronic element 27 is electrically connected to the circuit layer 21.

In an embodiment, the electronic element 27 is an active element, a passive element, or a combination of the active element and the passive element, wherein the active element may be a semiconductor chip, and the passive element may be a resistor, a capacitor, or an inductor. In one embodiment, the electronic element 27 is a passive element and is electrically connected to the circuit layer 21 via a plurality of conductive bumps 270 made of solder material. It should be understood that if the electronic element 27 is a semiconductor chip, it can be electrically connected to the circuit layer 21 in a manner of flip-chip, wire bonding, or other packaging methods.

As shown in FIG. 2D, an encapsulating layer 28 is formed on the first surface 23a of the insulating layer 23 of the circuit portion 2a, so that the electronic element 27 is covered by the encapsulating layer 28, wherein the encapsulating layer 28 is an Ajinomoto build-up film (ABF), which has an excellent binding with metal materials such as copper.

In an embodiment, the encapsulating layer 28 is defined with a first side 28a and a second side 28b opposing the first side 28a, and the encapsulating layer 28 is bonded to the first surface 23a of the insulating layer 23 via the first side 28a thereof. For example, the encapsulating layer 28 is formed on the circuit portion 2a by pressing/laminating, so that a second metal layer 280 can be formed on the second side 28b of the encapsulating layer 28 to facilitate the pressing/laminating of the encapsulating layer 28 on the circuit portion 2a, and the second metal layer 280 is exposed after the encapsulating layer 28 is bonded to the circuit portion 2a.

Furthermore, a material forming the encapsulating layer 28 is different from a material forming the insulating layer 23. Alternatively, the insulating layer 23 can also be made of ABF material, so that the encapsulating layer 28 and the insulating layer 23 are made of the same material.

As shown in FIG. 2E, a wiring layer 25 is formed on the encapsulating layer 28, and the wiring layer 25 is formed with a plurality of conductive vias 250 (e.g., conductive through vias) in the encapsulating layer 28, so that the first side 28a of the encapsulating layer 28 is in communication with the second side 28b by the conductive vias 250, and the wiring layer 25 is electrically connected to the circuit layer 21 by the conductive via 250.

In an embodiment, the wiring layer 25 is formed by a redistribution layer (RDL) process, and the material of the wiring layer 25 is copper.

Moreover, the manufacturing process of the conductive via 250 is to burn the second metal layer 280 and the encapsulating layer 28 with laser on the second side 28b of the encapsulating layer 28 to form a through hole exposed from the circuit layer 21, and a copper material is formed in the through hole by the RDL process adopted by the wiring layer 25. It should be understood that there are many methods for manufacturing the through molding via (TMV), but not limited to the above.

On the other hand, the first metal layer 22 can also be used to perform the RDL wiring process on the circuit portion 2a, so as to form another wiring layer 24 on the second surface 23b of the insulating layer 23, and the another wiring layer 24 is formed with a plurality of conductive blind vias 240 in the insulating layer 23, wherein the conductive blind vias 240 are electrically connected to the circuit layer 21. It should be understood that, in other embodiments, the first metal layer 22 can also be removed to form an opening exposing the circuit layer 21 on the second surface 23b of the insulating layer 23 to externally connect with such as circuit boards, package modules, or other electronic devices.

As shown in FIG. 2F, a solder-resist layer 26 with a plurality of openings 260 is formed on the second surface 23b of the insulating layer 23 and the second side 28b of the encapsulating layer 28, so that parts of the surfaces of the wiring layers 24, 25 are exposed from the openings 260 to externally connect with such as circuit boards, package modules, or other electronic devices.

Therefore, in the manufacturing method according to the present disclosure, the ABF material is used as the encapsulating layer 28, so that the wiring layer 25 can be well bonded on the encapsulating layer 28. Hence, compared with the prior art, the manufacturing method of the present disclosure can directly form the wiring layer 25 on the encapsulating layer 28 without forming a dielectric layer used to bond the wiring layer 25, so that the manufacturing time and the manufacturing materials can be effectively saved, and the manufacturing cost can be effectively reduced.

Furthermore, the manufacturing method of the present disclosure can directly process the ABF material by laser so as to form the through holes required for the conductive vias 250. Therefore, compared with the prior art, the manufacturing method of the present disclosure does not need to perform the manufacturing process of copper pillars and grinding operations, which not only saves manufacturing time and manufacturing materials to reduce manufacturing costs, but also can greatly reduce manufacturing steps to improve production efficiency.

Also, since the manufacturing method of the present disclosure uses the ABF material as the encapsulating layer 28, a full-panel specification can be adopted. Therefore, compared with the prior art that can only be used with a single unit specification or a wafer size specification, the present disclosure can greatly improve the efficiency and reduce the production cost to facilitate mass production.

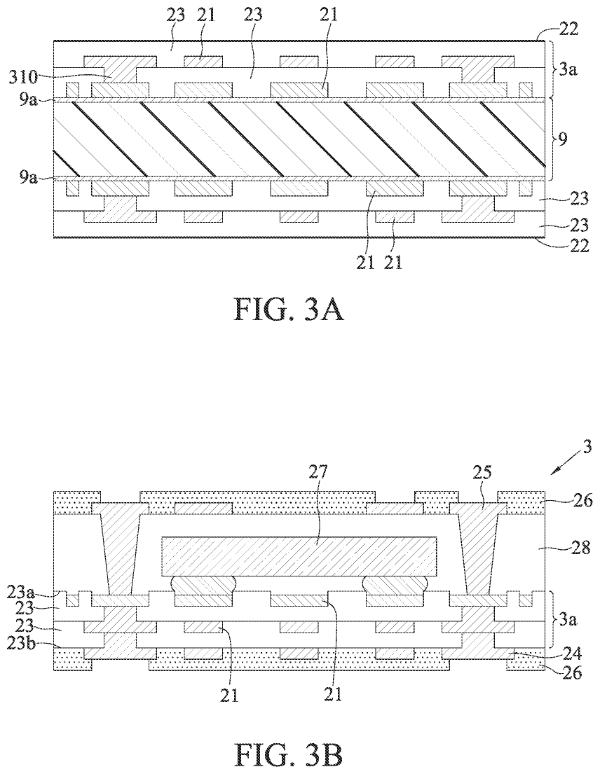

FIG. 3A to FIG. 3B are schematic cross-sectional views illustrating a method of manufacturing an electronic package 3 according to a second embodiment of the present disclosure. The difference between the second embodiment and the first embodiment lies in the number of wiring layers of a circuit portion 3a, and the other manufacturing processes are substantially the same, so the same parts will not be repeated.

As shown in FIG. 3A, a plurality of the insulating layers 23 and a plurality of the circuit layers 21 bonded to the plurality of insulating layers 23 are formed on the carrier 9, so that the plurality of insulating layers 23 and the plurality of circuit layers 21 are served as the circuit portion 3a.

In an embodiment, the plurality of circuit layers 21 are electrically connected with each other by conductive blind vias 310.

As shown in FIG. 3B, according to the manufacturing processes shown in FIG. 2B to FIG. 2F, the electronic package 3 with another wiring specification is obtained.

In an embodiment, the electronic package 3 is configured with four layers of wiring (two layers of the circuit layers 21 and two layers of the wiring layers 24, 25), while the electronic package 2 of the first embodiment is configured with three layers of wiring (single layer of the circuit layer 21 and two layers of the wiring layers 24, 25).

The present disclosure also provides an electronic package 2, which comprises: a circuit portion 2a, 3a, at least one electronic element 27, an encapsulating layer 28 and a wiring layer 25.

The circuit portion 2a, 3a has at least one insulating layer 23 and a circuit layer 21 bonded to the insulating layer 23, wherein the insulating layer 23 is defined with a first surface 23a and a second surface 23b opposing the first surface 23a, and the circuit layer 21 is exposed from the first surface 23a of the insulating layer 23.

The electronic element 27 is disposed on the first surface 23a of the insulating layer 23 of the circuit portion 2a, 3a and electrically connected to the circuit layer 21.

The encapsulating layer 28 is formed on the first surface 23a of the insulating layer 23 of the circuit portion 2a, 3a and covering the electronic element 27, wherein the encapsulating layer 28 is an Ajinomoto build-up film.

The wiring layer 25 is formed on the encapsulating layer 28, wherein the wiring layer 25 is formed with at least one conductive via 250 in the encapsulating layer 28, and the at least one conductive via 250 is electrically connected to the circuit layer 21.

In one embodiment, the electronic element 27 is a passive element.

In one embodiment, the electronic element 27 is electrically connected to the circuit layer 21 via a plurality of conductive bumps 270.

In one embodiment, a material forming the encapsulating layer 28 is different from a material forming the insulating layer 23.

In one embodiment, the electronic package 2, 3 further comprises another wiring layer 24 formed on the second surface 23b of the insulating layer 23, wherein the another wiring layer 24 is formed with at least one conductive blind via 240 in the insulating layer 23, and the at least one conductive blind via 240 is electrically connected to the circuit layer 21.

In view of the above, in the electronic package and the manufacturing method thereof according to the present disclosure, the ABF material is used as the encapsulating layer, so that the wiring layer can be well bonded onto the encapsulating layer. Therefore, the manufacturing method of the present disclosure can directly form the wiring layer on the encapsulating layer without forming a dielectric layer used to bond the wiring layer, so that the manufacturing time and the manufacturing materials can be effectively saved, and the manufacturing cost can be effectively reduced.

Furthermore, the manufacturing method of the present disclosure can directly process the ABF material by laser to form conductive vias. Therefore, the manufacturing method of the present disclosure does not need to perform the manufacturing process of copper pillars and grinding operations, which not only saves manufacturing time and manufacturing materials to reduce manufacturing costs, but also can greatly reduce manufacturing steps to facilitate improving production efficiency.

Also, since the manufacturing method of the present disclosure uses the ABF material as the encapsulating layer, a full-panel specification can be adopted. Therefore, the present disclosure can greatly improve the efficiency and reduce the production cost to facilitate mass production.

The above embodiments are provided for illustrating the principles of the present disclosure and its technical effect, and should not be construed as to limit the present disclosure in any way. The above embodiments can be modified by one of ordinary skill in the art without departing from the spirit and scope of the present disclosure. Therefore, the scope claimed of the present disclosure should be defined by the following claims.

What is claimed is:

1. An electronic package, comprising:
a circuit portion having at least one insulating layer and a circuit layer bonded to the insulating layer, wherein the insulating layer is defined with a first surface and a second surface opposing the first surface, and the circuit layer is exposed from the first surface of the insulating layer;
an electronic element disposed on the first surface of the insulating layer of the circuit portion and electrically connected to the circuit layer;
an encapsulating layer formed on the first surface of the insulating layer of the circuit portion and covering the electronic element, wherein the encapsulating layer is an Ajinomoto build-up film; and
a wiring layer formed on the encapsulating layer, wherein the wiring layer is formed with at least one conductive via in the encapsulating layer, and the at least one conductive via is electrically connected to the circuit layer.

2. The electronic package of claim 1, wherein the electronic element is a passive element.

3. The electronic package of claim 1, wherein the electronic element is electrically connected to the circuit layer via a plurality of conductive bumps.

4. The electronic package of claim 1, wherein a material forming the encapsulating layer is different from a material forming the insulating layer.

5. The electronic package of claim 1, further comprising another wiring layer formed on the second surface of the insulating layer, wherein the another wiring layer is formed with at least one conductive blind via in the insulating layer, and the at least one conductive blind via is electrically connected to the circuit layer.

6. A method of manufacturing an electronic package, comprising:
providing a circuit portion having at least one insulating layer and a circuit layer bonded to the insulating layer, wherein the insulating layer is defined with a first surface and a second surface opposing the first surface, and the circuit layer is exposed from the first surface of the insulating layer;
disposing an electronic element on the first surface of the insulating layer of the circuit portion, wherein the electronic element is electrically connected to the circuit layer;
forming an encapsulating layer on the first surface of the insulating layer of the circuit portion to cover the electronic element, wherein the encapsulating layer is an Ajinomoto build-up film; and
forming a wiring layer on the encapsulating layer, wherein the wiring layer extends into the encapsulating layer to form at least one conductive via electrically connected to the circuit layer.

7. The method of claim 6, wherein the electronic element is a passive element.

8. The method of claim 6, wherein the electronic element is electrically connected to the circuit layer via a plurality of conductive bumps.

9. The method of claim 6, wherein a material forming the encapsulating layer is different from a material forming the insulating layer.

10. The method of claim 6, further comprising forming another wiring layer on the second surface of the insulating layer, and forming at least one conductive blind via in the insulating layer, wherein the at least one conductive blind via is electrically connected to the circuit layer and the another wiring layer.
